(19) United States
(12) Patent Application Publication
(10) Pub. No.: US 2011/0091640 A1
(43) Pub. Date: Apr. 21, 2011

(54) NON-SHRINKING CERAMIC SUBSTRATE AND METHOD OF MANUFACTURING THE SAME

(75) Inventors: Jin Waun KIM, Hwaseong (KR); Seung Gyo Jeong, Hwaseong (KR)

(73) Assignee: SAMSUNG ELECTRO-MECHANICS CO., LTD., Suwon (KR)

(21) Appl. No.: 12/973,557

(22) Filed: Dec. 20, 2010

Related U.S. Application Data
(62) Division of application No. 12/475,318, filed on May 29, 2009.

(30) Foreign Application Priority Data
Oct. 17, 2008 (KR) 10-2008-0101934

(51) Int. Cl. H05K 3/10; B05D 5/12; H01L 21/288

(52) U.S. Cl. 427/125; 427/58; 427/126.2; 205/123

(57) ABSTRACT

A method of manufacturing a non-shrinking ceramic substrate according to an aspect of the invention may include: preparing a ceramic laminate having a via electrode therein; firing the ceramic laminate so that a void is formed at the interface between the via electrode and the ceramic laminate; and performing plating to fill the void with a conductive material.

### CROSS-REFERENCE TO RELATED APPLICATIONS

This application is a divisional of U.S. patent application Ser. No. 12/475,318 entitled “Non-Shrinking Ceramic Substrate And Method Of Manufacturing The Same,” filed on May 29, 2009, which claims the priority of Korean Patent Application No. 2008-0101934 filed on Oct. 17, 2008, in the Korean Intellectual Property Office, the disclosures of all of which are incorporated herein by reference.

### BACKGROUND OF THE INVENTION

1. Field of the Invention

The present invention relates to a non-shrinking ceramic substrate and a method of manufacturing the non-shrinking ceramic substrate, and more particularly, to a non-shrinking ceramic substrate and a method of manufacturing the non-shrinking ceramic substrate that can prevent defects caused by voids formed in a ceramic laminate.

2. Description of the Related Art

Recently, with the continuing trend towards miniaturization in electronic components, small modules and substrates have been developed as the electronic components are formed into micropatterns and thin films with high precision.

However, when printed circuit boards (PCBs) being widely used are used in electronic components, defects, such as a reduction in size, signal loss in the high-frequency domain, and a deterioration in reliability at high temperatures and humidity, occur.

In order to eliminate these defects, substrates using ceramics have been used instead of PCBs. Ceramic substrates chiefly include a ceramic composition that contains a large amount of glass that allows low-temperature co-firing.

There are various kinds of methods of manufacturing low temperature co-fired ceramic substrates. These methods may be classified into shrinkage methods and non-shrinking methods according to whether ceramic substrates shrink or not in the firing process.

Specifically, in the shrinkage method, a ceramic substrate is manufactured as the ceramic substrate shrinks in a firing process. However, since the ceramic substrate does not shrink evenly in all directions, the shrinkage method causes dimensional changes in a planar direction of the ceramic substrate.

The shrinkage of the ceramic substrate in the planar direction causes the deformation of printed circuit patterns included in the ceramic substrate. This causes defects, such as a decrease in accuracy of the pattern position and pattern disconnection.

In order to solve the defects caused by the shrinkage method, a non-shrinking method has been proposed to prevent the shrinkage of the ceramic substrate in the planar direction during the firing process.

According to the non-shrinking method, a firing process is performed as constraining layers are formed on both surfaces of a ceramic substrate. The constraining layers prevent the shrinkage of the ceramic substrate during firing and allow the ceramic substrate to only shrink in a thickness direction.

Ceramic green sheets form respective layers in a ceramic substrate that is manufactured using a non-shrinking method. Parts of the ceramic green sheets are punched to form via holes. Then, via electrodes are formed by filling the via holes with conductive paste. The via electrodes electrically connect internal electrodes and external electrodes with each other that are formed on the ceramic green sheets.

However, since via electrodes, external electrodes, internal electrodes, and ceramic green sheets constituting a ceramic laminate are formed of different materials from each other, even when ceramic substrates are manufactured using this non-shrinking method, voids are formed at the interfaces therebetween due to differences in shrinkage characteristics and differences in thermal expansion coefficients in the firing process.

The formed voids cause electrical disconnection of the via electrodes, the external electrodes, and the internal electrodes from each other. Also, an expensive ceramic substrate having hundreds of thousands of via electrodes formed therein must be discarded due to voids, inflicting heavy economic losses.

### SUMMARY OF THE INVENTION

An aspect of the present invention provides a non-shrinking ceramic substrate and a method of manufacturing the non-shrinking ceramic substrate that can prevent a poor electric connection caused by voids formed between internal electrodes and external electrodes when firing a ceramic laminate.

According to an aspect of the present invention, there is provided a method of manufacturing a non-shrinking ceramic substrate, the method including: preparing a ceramic laminate having a via electrode therein; firing the ceramic laminate so that a void is formed at the interface between the via electrode and the ceramic laminate; and performing plating to fill the void with a conductive material.

The plating may include electroplating or electroless plating.

The conductive material for the plating may include one selected from the group consisting of silver (Ag), nickel (Ni), nickel/copper (Ni/Cu), and tin (Sn).

According to another aspect of the present invention, there is provided a non-shrinking ceramic substrate including: a ceramic laminate having a plurality of green sheets laminated onto each other; an internal electrode provided in the ceramic laminate; a via electrode provided through ceramic laminate such that the via electrode is electrically connected to the internal electrode; an external electrode provided at the surface of the ceramic laminate while the external electrode is adjacent to the via electrode, and electrically connected to the via electrode; and a plating portion filling a void formed at the interface between the via electrode and the ceramic laminate when the ceramic laminate is fired.

The plating portion may include one selected from the group consisting of silver (Ag), nickel (Ni), nickel/copper (Ni/Cu), and tin (Sn).

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a cross-sectional view illustrating the state before a non-shrinking ceramic substrate is fired according to an exemplary embodiment of the present invention;

FIG. 2 is a cross-sectional view the state after the non-shrinking ceramic substrate, illustrated in FIG. 1, is fired; and

FIG. 3 is a cross-sectional view illustrating a plating portion in a non-shrinking ceramic substrate according to an exemplary embodiment of the present invention.

### DETAILED DESCRIPTION OF THE PREFERRED EMBODIMENT

Exemplary embodiments of the present invention will now be described in detail with reference to the accompanying drawings.

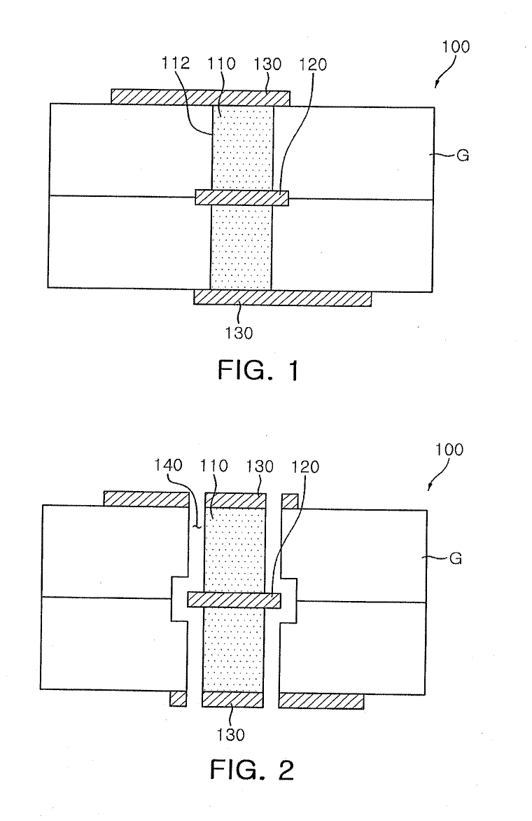

A non-shrinking ceramic substrate and a method of manufacturing the same according to exemplary embodiments of the invention will be described in more detail with reference to FIGS. 1 through 3.

FIG. 1 is a cross-sectional view illustrating the state before a non-shrinking ceramic substrate is fired according to an exemplary embodiment of the invention. FIG. 2 is a view illustrating the state after the non-shrinking substrate, illustrated in FIG. 1, is fired.

Referring to FIGS. 1 and 2, a method of manufacturing a non-shrinking ceramic substrate includes an operation of preparing a ceramic laminate 100 that has a via electrode 110 therein.

A non-shrinking ceramic substrate before a firing process is performed includes a ceramic laminate 100, the via electrode 110, an internal electrode 120 and external electrodes 130.

The ceramic laminate 100 is formed by laminating a plurality of ceramic green sheets G onto each other. Specifically, an organic binder, a dispersing agent, and a mixed solvent are added to glass-ceramic powder, and a mixture thereof is dispersed using a ball mill to obtain a slurry.

Then, the slurry is filtered through a filter, bubbles are removed from the flirted slurry, and ceramic green sheets having a predetermined thickness are formed using the resultant slurry according to the doctor blade method.

The via electrode 110 is formed through the ceramic laminate 100 and electrically connects the internal electrode 120 and the external electrodes 130 to each other.

When ceramic green sheets are manufactured, the via electrode 110 is formed by forming a via hole 112 in each of the ceramic green sheets and then filling the via hole 112 with conductive paste.

Here, the conductive paste is formed of silver (Ag) having a high electrical conductivity. However, the conductive paste is not limited to silver and can be formed of Ni, Pb, W, or Sn.

The internal electrode 120 is formed between the ceramic green sheets G and electrically connected to the external electrodes 130 through the via electrode 110.

The external electrode 130 is provided by screen-printing conductive paste onto the surface of the ceramic laminate 100. Here, the external electrodes 130 completely cover the entire surface of the via electrode 110.

Then, after the ceramic laminate 100 is prepared, the ceramic laminate 100 is fired at a predetermined temperature.

Here, in the firing process, voids 140 are formed at the interface of the via electrode 110 and the ceramic laminate 100 due to a difference in shrinkage characteristics and a difference in thermal expansion coefficients. Here, the void 140 may refer to a separated opening such as a crack.

The void 140 electrically disconnects the via electrode 110, the external electrode 130, and the internal electrode 120 from each other. An expensive ceramic substrate must be discarded due to the generation of voids.

Therefore, a plating process is performed to form a plating portion 150 such that the plating portion 150 fills the void 140.

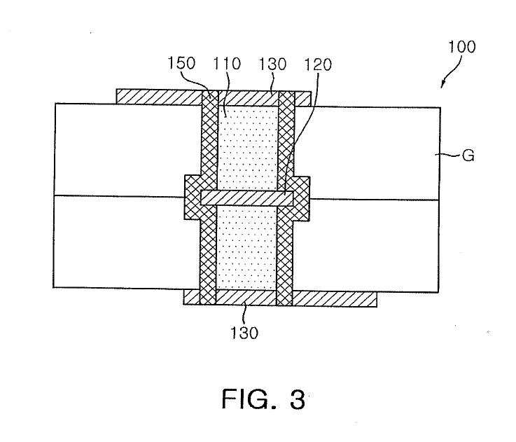

FIG. 3 is a cross-sectional view illustrating a plating portion of a non-shrinking ceramic substrate according to an exemplary embodiment of the invention.

Referring to FIG. 3, the plating portion 150 is formed to fill the void 140. The plating portion 150 may fill the void 140 using an electroplating method.

The electroplating method refers to a method of filling a void with a metal, such as silver (Ag), by plating the metal onto one surface of the void according to the principle of electrolysis.

However, in an electroplating method, the metal is not limited to silver (Ag), and may be selected, from one metal of nickel (Ni), nickel/copper (Ni/Cu), and tin (Sn).

In this embodiment, the electroplating method is used in which the plating portion 150 is formed along the void 140. However, the invention is not limited thereto, and electroless plating can be applied.

Electroless plating refers to a plating method using a chemical reaction without the use of electricity. Electroless plating includes two methods, that is, immersion plating and reduction plating.

Therefore, the non-shrinking ceramic substrate according to this embodiment of the invention improves electric connectivity by the plating portion 150 filling the void 140 formed between the ceramic laminate 100 and the via electrode 110. Therefore, economic loss due to expensive substrates being discarded due to a decrease in electrical connection caused by the void 140 can be prevented.

As set forth above, according to exemplary embodiments of the invention, as a plating portion fills a void formed at the interface of a via electrode, an internal electrode, and an external electrode, a poor electrical connectivity due to the void can be prevented.

While the present invention has been shown and described in connection with the exemplary embodiments, it will be apparent to those skilled in the art that modifications and variations can be made without departing from the spirit and scope of the invention as defined by the appended claims.

What is claimed is:

1. A method of manufacturing a non-shrinking ceramic substrate, the method comprising:
preparing a ceramic laminate having a via electrode therein;
firing the ceramic laminate so that a void is formed at the interface between the via electrode and the ceramic laminate; and
performing plating to fill the void with a conductive material.

2. The method of claim 1, wherein the plating comprises electroplating or electroless plating.

3. The method of claim 1, wherein the conductive material for the plating comprises one selected from the group consisting of silver (Ag), nickel (Ni), nickel/copper (Ni/Cu), and tin (Sn).
